(19) United States
(12) Patent Application Publication
(10) Pub. No.: US 2022/0199360 A1
(43) Pub. Date: Jun. 23, 2022

(54) ELECTRON MICROSCOPE USING ARTIFICIAL INTELLIGENCE TRAINING DATA

(71) Applicant: COXEM CO., LTD, Daejeon (KR)

(72) Inventor: Junhee LEE, Daejeon (KR)

(21) Appl. No.: 17/603,951

(22) PCT Filed: Apr. 13, 2020
(86) PCT No.: PCT/KR2020/004962

§ 371 Date: Oct. 15, 2021

(30) Foreign Application Priority Data
Apr. 30, 2019 (KR) 10-2019-0050578

(51) Int. Cl. H01J 37/26; G06N 3/08; H01J 37/21

(52) U.S. Cl. CPC H01J 37/263; G06N 3/08; H01J 37/28; H01J 37/26; H01J 37/21

(57) ABSTRACT

The present disclosure relates to an electron microscope having a deep learning module in which electron microscopy images and control parameters are used as training input information of the deep learning model, and the deep learning model trained using focus, contrast and brightness among the control parameters as targets of the deep learning model generates a command for optimal target it is possible to automatically provide a sample image with high quality based on data trained based on artificial intelligence without any manual manipulation of control parameter values, thereby allowing beginners as well as people with advanced skills to easily use the electron microscope, which contributes to thriving electron microscope market.

### TECHNICAL FIELD

The present disclosure relates to an electron microscope, and more particularly, to an electron microscope using artificial intelligence training data for allowing even beginners to easily observe images of samples with high quality using image quality datasets acquired by training a relationship between control parameters when imaging with the electron microscope, images corresponding to the control parameters and image quality through a deep learning model.

### BACKGROUND ART

To observe semiconductors, displays and component materials, a transmission electron microscope (TEM) and a scanning electron microscope (SEM) are used.

The transmission electron microscope is a device used to detect the phase, properties, components and defects of a material, and after a thin film sample is fabricated and fixed, an electron beam of a high potential difference is incident on the sample surface and transmitted through the sample to analyze the phase and components of the sample.

The scanning electron microscope is a device which scans a sample with a focused electron beam to observe the surface condition of the sample or analyze the components of the sample using an electron signal related to secondary electrons or backscattered electrons emitted from the sample.

FIG. 1 is a configuration diagram of the common scanning electron microscope, and the scanning electron microscope includes a column 10, a sample chamber 20, a. detector 30, an image acquisition module 40, a controller 50 and a computer 60.

The column 10 is where devices for scanning the sample with an electron beam are installed, and the detector 30 is installed on one side of the column to detect secondary electrons or backscattered electrons emitted from the sample.

The image acquisition module 40 receives a detection signal from the detector 30 and processes a sample surface image, and the controller 50 controls each device based on various parameter values necessary to operate the electron microscope.

The computer 60 includes an input device for input of a user input signal for adjusting the parameter values, and a display device to allow a user to observe the sample image, so the user can observe the sample image while adjusting the parameter values.

The scanning electron microscope has a series of very complicated and difficult processes to observe the image by interaction between the accelerated electrons and the sample. That is, for accurate analysis of the sample, the user needs to acquire an image with desired high quality by precisely adjusting the parameters such as the working distance (WD), the contrast, the brightness, the position of the stage, the number of electrons emitted from the sample and the voltage, under the understanding of charged particle optics and the properties of the sample.

To acquire the sample image with high quality using the electron microscope, advanced level of professional knowledge and skill is required. Accordingly, it is very difficult for beginners to acquire sample images with high quality using the electron microscope.

### DISCLOSURE

### Technical Problem

To overcome the drawback of the background art, the present disclosure is aimed at generating a command for optimal target in a trained deep learning model in which electron microscopy images and control parameters are used as training input information of the deep learning model, and the deep learning model is trained using focus, contrast and brightness among the control parameters as targets of the deep learning model.

### Technical Solution

To solve the problem, according to an aspect of the present disclosure, there is provided an electron microscope using artificial intelligence training data, in which electron microscopy images and control parameters are used as training input information of a deep learning model, and the deep learning model trained using the level of image quality such as focus, contrast and brightness among the control parameters as targets of the deep learning model generates a command for optimal target.

Here, the command may be a command for adjusting the focus, contrast and brightness, and a start condition of the deep learning module may be at least one of stage movement, accelerating voltage change or spot size change when a filament is on.

Additionally, preferably, the control parameters are classified into a plurality of parameter groups according to an extent of influence on image quality and whether the control parameters are usable as operational conditions, and a set of control parameters only includes parameters that affect the image quality and parameters that do not affect the image quality but are usable as the operational conditions.

Additionally, when a shutter command is inputted from a user, an maximum point and minimum point may be computed for a focus, contrast and brightness curve before a time point at which the shutter command is inputted. And a highest score may be assigned to parameter values corresponding to focus, contrast and brightness values at the time point at which the shutter command is inputted under an assumption that optimum focus, contrast and brightness correspond to the time point at which the shutter command is inputted, and a lowest score may be assigned to parameter values of the corresponding maximum, minimum point. And to differently assign the scores depending on a manipulation level of the user, the deep learning module may receive an input of manipulation level information from the user when the electron microscope operates.

### Advantageous Effects

According to the present disclosure. it is possible to automatically provide a sample image with high quality based on data trained based on artificial intelligence without any manual manipulation of control parameter values, thereby allowing people with advanced skills as well as beginners to easily use the electron microscope, so even beginners can acquire high quality images that the people with advanced skills acquire.

### BRIEF DESCRIPTION OF THE DRAWINGS

FIG. 1 is a configuration diagram of a common electron scanning microscope.

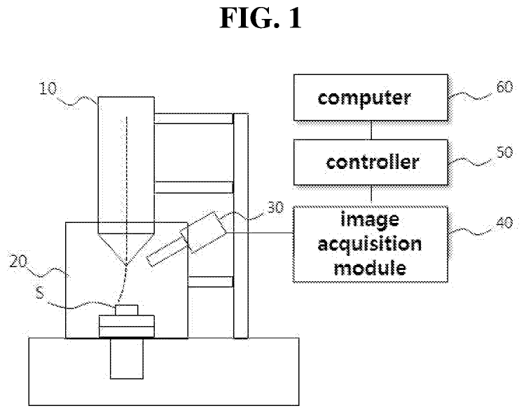

FIG. 2 is a configuration diagram of an electron microscope using artificial intelligence training data according to an embodiment of the present disclosure.

FIG. 3 is a diagram illustrating artificial intelligence learning according to an embodiment of the present disclosure.

FIG. 4 is a reference diagram for describing a target setting method according to embodiment an of the present disclosure.

FIG. 5 is a diagram for describing an image acquisition process of an electron microscope using artificial intelligence training data.

### DETAILED DESCRIPTION

Hereinafter, a preferred embodiment of the present disclosure will be described in detail with reference to the accompanying drawings.

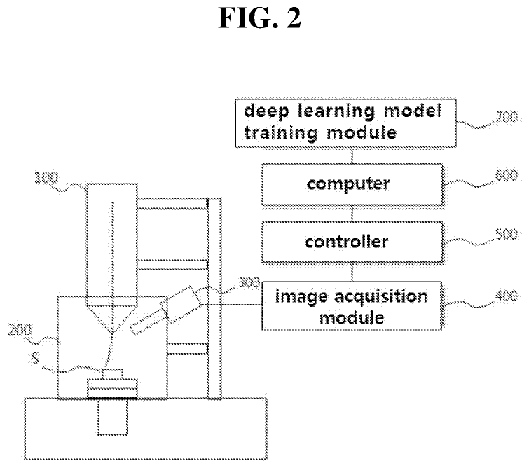

FIG. 2 is a configuration diagram of an electron microscope using artificial intelligence training data according to an embodiment of the present disclosure, and the electron microscope includes a column 100, a sample chamber 200, a detector 300, an image acquisition module 400, a controller 500, a computer 600 and a deep learning module 700.

The column 100 is configured to scan a sample with an electron beam, and although not shown in detail in the drawing, includes an electron gun to produce the electron beam, a condenser lens, a deflector, an objective lens and an aperture.

The detector 300 is installed on one side of the column 100 to detect secondary electrons or backscattered electrons emitted from the sample.

The image acquisition module 400 receives a detection signal from the detector 300 and processes a sample surface image.

The controller 500 is configured to control each device based on various parameter values necessary to operate the electron microscope, and controls the operation of each device according to the control parameter values based on a user's manipulation signal inputted through the computer 600 or data trained by the deep learning module 700.

The deep learning module 700 generates a command for optimal target in a trained deep learning model in which images captured with the electron microscope and control parameters at that time are used as training input information, and the deep learning model is trained using focus, contrast and brightness among the control parameters as targets. The deep learning module 700 may be integrally implemented in the computer 600, and is not limited to a particular application and may be built in a server connected via an internet or a wireless communication network to collect various types of image quality datasets in a variety of applications.

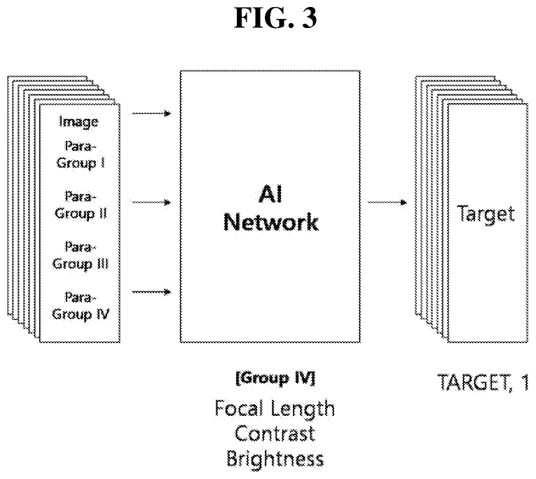

The training process using the deep learning module 700 will be described with reference to FIG. 3 below.

Referring to FIG. 3, as described above, electron microscopy images and control parameters as training input information are inputted to an artificial intelligence network. The control parameters may be classified into four parameter groups according to the extent of influence on the image quality.

Group I may include parameters that do not affect the image quality and deep learning model training at all, for example, version, date and image type etc.

Group II may include parameters that do not affect the image quality at all but may be used as operational conditions, for example, scan rate, stage position, rotation and pixel size etc.

Group III may include parameters that indirectly affect the image quality, for example, spot size, number of electrons, voltage, and beam alignment etc,

Group IV may include parameters that directly affect the image quality, for example, focal length, contrast and brightness etc.

This embodiment uses the parameters that directly affect the image quality such as focal length, contrast and brightness as targets of the deep learning model. Here, the targets may be image quality scores for each of varying focus, contrast and brightness values. For example, the image quality of electron microscopy images acquired by varying each of the focus, contrast and brightness values may be scored as values of 1˜9. The scoring value indicates higher quality as its number is higher.

The following will describe a method of determining the target.

In general, the user observes an image while manipulating the electron microscope, and when a high quality image is acquired, presses a shutter command to acquire the corresponding image. It is preferred that the user is unaware of the training process in the deep learning model process of the electron microscope, and to this end, the present disclosure gives the highest score when the shutter command is pressed by the user under the assumption that a photographic image acquired by pressing the shutter command is recognized as an image with highest quality. Additionally, weights may be added to the scores by grading according to professionality or skillfulness of the user. For example, it is possible to classify the user into beginner (low), intermediate (middle) and expert thigh), and define the score range for beginners as 1˜5, the score range for intermediates as 1˜7, and the score range for experts as 1˜9. To this end, it is preferred to input electron microscope manipulation level information of the user as high, middle and low at the initial time point at which the user use the electron microscope.

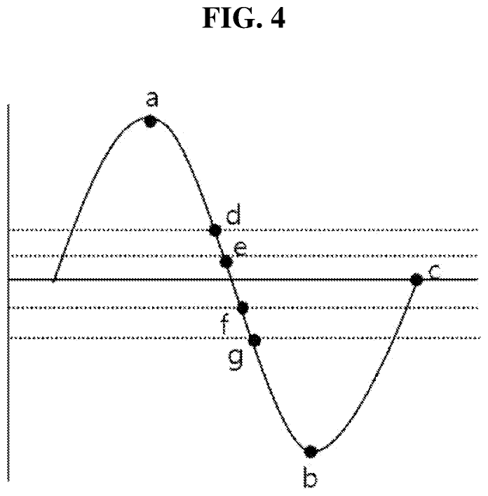

For determining the scores, the user may set a target using maximum and. minimum points of focus, contrast and brightness and collect data until the user presses the shutter command, and this process is shown in FIG. 4.

FIG. 4 shows an example of a control parameter curve until the time point c at which the user presses the shutter command for an optimal image after the user observes the image quality while manipulating the electron microscope. The control parameter may be any one of focus, contrast and brightness. When the user stops the manipulation at the point “c” and presses the shutter command, there are maximum and minimum points a, b and the lowest score is assigned to the maximum and minimum points. Additionally, the distance between the point “c” and the maximum and minimum points may be divided into n (for example, nine) in the y axis direction, and scores may be assigned according to the distance from the point “c”.

In FIG. 4 for example, since the points “e” and “f”, and the points “d” and “g” are disposed at the same distance from the point “c”, the same score is assigned respectively, and as the distance from the point “c” is longer, a lower score is assigned.

A method of collecting electron microscopy data through this process can easily and effectively collect a large amount of data necessary for deep learning by collecting data acquired while users of various levels use the electron microscope without a separate process of collecting data for training.

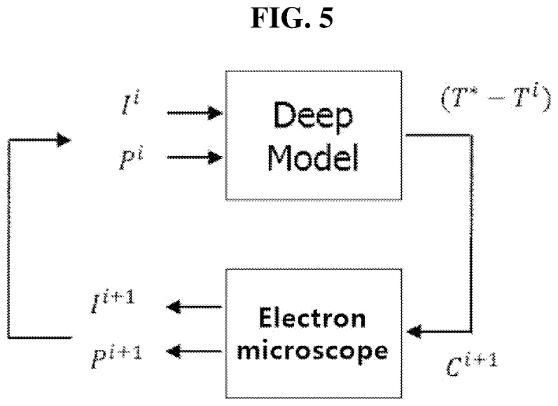

FIG. 5 is a diagram illustrating an image acquisition process of the electron microscope using artificial intelligence training data.

When the user operates the electron microscope, electron microscopy images and control parameters Pⁱ are inputted to the deep learning model as training input information. The deep learning model determines a target T of the corresponding electron microscopy image according to the training result, identifies a difference by comparing the determined target Tⁱ with the optimal target T* and outputs a control signal Cⁱ⁺¹ for compensating for the difference to the electron microscope. Here, the control signal Cⁱ⁺¹ is a control signal for changing the control parameter according to the training result. Accordingly, the electron microscope inputs a new image Iⁱ⁺¹ and a control parameter Pⁱ⁺¹ to the deep learning model, and the deep learning model iteratively performs a process of comparing the target Tⁱ⁺¹ with the optimal target T*, and when the target outputted from the deep model is the optimal target T*, i.e., when an image having the score of 9 is acquired, the corresponding image is provided to the user. IF the period of time after the control signal Cⁱ⁺¹ is inputted to the electron microscope until the new image Iⁱ⁺¹ and the control parameter Pⁱ⁺¹ are acquired and then the new target Tⁱ⁺¹ is acquired is defined as one cycle control response time, the optimal target T* is reached in a few cycles to provide the optimal quality image to the user using artificial intelligence. Accordingly, as one cycle control response time is shorter, the user will feel higher satisfaction, and the time is preferably within 1˜2 seconds.

Hereinafter, the operation process of the electron microscope using artificial intelligence training data according to the present disclosure will be described with reference to the accompanying drawings.

When the user manipulates the computer 600 to acquire an electron microscopy image, control parameter values are transmitted to the controller 500, and the controller 500 controls the operation of each device corresponding to the control parameter values.

When an electron beam is irradiated on the sample S according to the control signal from the controller 500, the detector 300 detects secondary electrons or backscattered electrons emitted from the sample, and transmits to the image acquisition module 400.

The image acquisition module 400 receives a detection signal from the detector 300, processes a sample surface image and transmits it to the computer 600, and the user changes the control parameters until a high quality image is acquired while observing the test image displayed on the screen of the computer 600.

In this manipulation process, the control parameters in particular, a focus, contrast and brightness curve that are important in the present disclosure are changed, and the image qualities are changed every time point. When the user presses the shutter command for image storage, the image at that time is regarded as an optimal image. The period of time from the time point of the maximum point a to the time point c at which the shutter s pressed is divided into ranges, and key control parameter values (focus, contrast and brightness) and scores in each range are stored as targets.

The collected data may be used for further training of the deep learning model, and in the common control process, electron microscopy images are acquired using the trained deep learning model. When the deep learning model is trained using a larger amount of data, the deep learning model exhibits better performance, so automatically collecting data is an important factor for improving the deep learning model.

As shown in FIG. 5, an image with high image quality is acquired by iteratively performing the process of comparing the target Tⁱ of the corresponding electron microscopy image determined based on input information of the trained deep learning model such as the electron microscopy images Iⁱ and the parameters Pⁱ with the optimal target T*, and the process of controlling the electron microscope using the resulting compensation control signal Cⁱ⁺¹, and the image is provided to the user.

Although the present disclosure has been described with respect to the above-mentioned preferred embodiments, a variety of modifications or changes may be made without departing from the spirit and scope of the present disclosure. Therefore, the scope of the appended claims will include such modifications and changes that belong to the spirit of the present disclosure.

What is claimed is:

1. An electron microscope using artificial intelligence training data, the electron microscope having a deep learning module in which electron microscopy images and control parameters are used as training input information of the deep learning model, and the deep learning model trained using focus, contrast and brightness among the control parameters as targets of the deep learning model generates a command for optimal target.

2. The electron microscope using artificial intelligence training data according to claim 1, wherein the command is a command for adjusting the focus, contrast and brightness.

3. The electron microscope using artificial intelligence training data according to claim 1, wherein a start condition of the deep learning module is at least one of stage movement, accelerating voltage change or spot size change when a filament is on.

4. The electron microscope using artificial intelligence training data according to claim 1, wherein the control parameters are classified into a plurality of parameter groups according to an extent of influence on image quality and whether the control parameters are usable as operational conditions, and a set of control parameters only includes parameters that affect the image quality and parameters that do not affect the image quality at all but are usable as the operational conditions.

5. The electron microscope using artificial intelligence training data according to claim 1, wherein when a shutter command is inputted from a user, an maximum point and minimum point are computed for a focus, contrast and brightness curve before a time point at which the shutter command is inputted, a highest score is assigned to a parameter value at the time point at which the shutter command is inputted and a lowest score is assigned to a parameter value of the maximum point and minimum point.

6. The electron microscope using artificial intelligence training data according to claim 1, wherein the deep learning module receives an input of manipulation level information from a user when the electron microscope operates, and differently sets a score range depending on a manipulation level of the user.
